(19) United States
(12) Patent Application Publication
(10) Pub. No.: US 2026/0013301 A1
(43) Pub. Date: Jan. 8, 2026

(54) DISPLAY DEVICE AND METHOD FOR MANUFACTURING THE SAME

(71) Applicant: Samsung Display Co., LTD., Yongin-si (KR)

(72) Inventors: Tae Gyun KIM, Yongin-si (KR); Ki Bum KIM, Yongin-si (KR); So Young LEE, Yongin-si (KR)

(73) Assignee: Samsung Display Co., LTD., Yongin-si (KR)

(21) Appl. No.: 19/194,685

(22) Filed: Apr. 30, 2025

(30) Foreign Application Priority Data
Jul. 4, 2024 (KR) 10-2024-0088308

(51) Int. Cl. H10H 29/80; H10H 20/819; H10H 29/01; H10H 29/855

(52) U.S. Cl. CPC H10H 29/8321; H10H 29/012; H10H 29/032; H10H 29/842; H10H 20/819; H10H 29/855

(57) ABSTRACT

A display device and a method of manufacturing the display device are provided. A display device includes a connection electrode disposed on a substrate, light emitting elements disposed on the connection electrode and extending in the thickness direction of the substrate, a first insulating layer surrounding a side and an upper surface of the light emitting elements, a second insulating layer disposed on the first insulating layer disposed on the upper surface of the light emitting elements and a common electrode disposed on the upper surface of the light emitting elements, the common electrode is electrically connected to the light emitting elements through a through hole that penetrates the first insulating layer and the second insulating layer to expose the upper surface of the light emitting elements.

### CROSS-REFERENCE TO RELATED APPLICATION(S)

This application claims priority to and benefits of Korean Patent Application No. 10-2024-0088308 under 35 U.S.C. § 119, filed on Jul. 4, 2024, in the Korean Intellectual Property Office, the entire contents of which are incorporated herein by reference.

### BACKGROUND

### 1. Technical Field

The disclosure relates to a display device and a method for manufacturing the same.

### 2. Description of the Related Art

The importance of display devices is gradually increasing along with the development of multimedia. In response to this, various display devices such as liquid crystal display devices and light emitting display devices are being developed. Among these, light emitting display device may include a display panel including light emitting elements, and is applied to various types of electronic devices, including portable electronic devices and televisions, as well as virtual reality (VR) devices and augmented reality (AR) devices.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects and features of embodiments are to provide a method for manufacturing a display device that may prevent short circuits while protecting the four sides of a light emitting element during etching of a wafer-to-wafer connection electrode, and a display device manufactured by this method.

However, the disclosure is not limited to those set forth herein. The above and other embodiments of the disclosure will become more apparent to one of ordinary skill in the art to which the disclosure pertains by referencing the detailed description of the disclosure given below.

According to one or more embodiments, a display device may include a connection electrode disposed on a substrate; light emitting elements disposed on the connection electrode and extending in a thickness direction of the substrate; a first insulating layer surrounding a side surface and an upper surface of the light emitting elements, a second insulating layer disposed on the first insulating layer disposed on the upper surface of the light emitting elements and a common electrode disposed on the upper surface of the light emitting elements, wherein the common electrode is electrically connected to the light emitting elements through a through hole that penetrates the first insulating layer and the second insulating layer to expose the upper surface of the light emitting elements.

In an embodiment, the side surface of the light emitting elements may form a first acute angle with a lower surface of the light emitting elements, wherein an inclined surface of the first insulating layer forms a second acute angle with a surface extending from the lower surface of the light emitting elements, and the second acute angle is greater than the first acute angle.

In an embodiment, a side surface of the connection electrode and a side surface of the first insulating layer may be mutually aligned and disposed in a straight line.

In an embodiment, the connection electrode may include a first connection electrode disposed at a lower surface of the connection electrode and a second connection electrode disposed on the first connection electrode, wherein the first connection electrode and the second connection electrode have one or more layers.

In an embodiment, a thickness of the second insulating layer on an upper portion of the light emitting elements may be less than a thickness of the first insulating layer.

In an embodiment, a slope of the first insulating layer may become thicker as being closer from the connection electrode to the common electrode.

In an embodiment, the display device may further comprise a third insulating layer disposed between an upper portion of the light emitting elements and the first insulating layer.

In an embodiment, wherein the light emitting elements may include a semiconductor stack and a contact electrode disposed at an end portion of the semiconductor stack, wherein the semiconductor stack may include a first semiconductor layer, an active layer, and a second semiconductor layer that are sequentially stacked.

In an embodiment, the semiconductor stack may further include a third semiconductor layer disposed on the second semiconductor layer.

In an embodiment, the contact electrode may include a first contact electrode and a second contact electrode, wherein the first contact electrode is disposed on a surface of the first semiconductor layer and the second contact electrode is disposed on an upper surface of the second semiconductor layer.

In an embodiment, the display device may further include a lens-shaped optical member on a light-emitting element layer including the light emitting elements and the common electrode.

In an embodiment, a method of manufacturing a display device may include bonding a backplane substrate including a first connection electrode layer and a base substrate having a second connection electrode layer and a semiconductor stack; etching the semiconductor stack using a first mask; forming a plurality of element insulating layers and planarizing steps formed by the semiconductor stack; etching the first connection electrode layer and the second connection electrode layer using a second mask and forming a common electrode on the semiconductor stack.

In an embodiment, the planarizing of the steps formed by the semiconductor stack may include, forming a first element insulating layer to cover the semiconductor stack on the backplane substrate; forming a second element insulating layer on the first element insulating layer and planarizing an upper surface of the second element insulating layer by a chemical mechanical polishing (CMP) process.

In an embodiment, the bonding of the base substrate may comprise, forming a first connection electrode layer on the backplane substrate, forming a second connection electrode layer on the semiconductor stack of the base substrate, arranging the first connection electrode layer and the second connection electrode layer to contact each other and bonding the first connection electrode layer and the second connection electrode layer and removing the base substrate from the semiconductor stack.

In an embodiment, wherein the first mask may be an insulating hard mask.

In an embodiment, the second mask may be a photoresist mask.

In an embodiment, the etching the first connection electrode layer and the second connection electrode layer using the second mask may include: forming the second mask on a second insulating layer to overlap a light emitting area, etching the first connection electrode layer and the second connection electrode layer using the second mask, and removing the second mask by ashing.

In an embodiment, the forming of the common electrode on the semiconductor stack may comprise: forming a through hole penetrating a first element insulating layer and a second element insulating layer on an upper surface of the semiconductor stack to expose at least a portion of the upper surface of the semiconductor stack and forming the common electrode so that the common electrode contacts the semiconductor stack through the through hole.

In an embodiment, the forming of the common electrode on the semiconductor stack may further comprise, the filling an organic layer between light emitting elements including the semiconductor stack and the connection electrode.

In an embodiment, the method may further comprise forming a lens-shaped optical member on the light emitting element layer including the light emitting elements and the common electrode.

In an embodiment, an electronic device may comprise a display panel including light emitting elements; a connection electrode disposed on a substrate; the light emitting elements disposed on the connection electrode and extending in a thickness direction of the substrate; a first insulating layer surrounding a side surface and an upper surface of the light emitting elements; a second insulating layer disposed on the first insulating layer disposed on the upper surface of the light emitting elements; and a common electrode disposed on the upper surface of the light emitting elements, wherein the common electrode is electrically connected to the light emitting elements through a through hole that penetrates the first insulating layer and the second insulating layer to expose the upper surface of the light emitting elements.

The side surface of the light emitting elements may form a first acute angle with a lower surface of the light emitting elements, and an inclined surface of the first insulating layer forms a second acute angle with a surface extending from the lower surface of the light emitting elements, and the second acute angle is greater than the first acute angle.

A side surface of the connection electrode and a side surface of the first insulating layer may be mutually aligned and disposed in a straight line.

The connection electrode may include a first connection electrode disposed at a lower surface of the light emitting elements and a second connection electrode disposed on the first connection electrode, and the first connection electrode and the second connection electrode have one or more layers.

A thickness of the second insulating layer on an upper portion of the light emitting elements may be less than a thickness of the first insulating layer.

The electronic device of claim 21, wherein the electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

According to the embodiments, a display device and a method for manufacturing a display device that minimize short circuits between a pixel electrode and a light emitting element may be provided.

Accordingly, the manufacturing efficiency of a display panel including light emitting elements and a display device including the same may be increased and yield improved.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment.

FIG. 2 is a schematic plan view illustrating an embodiment of area A of FIG. 1.

FIG. 3 is a schematic cross-sectional view illustrating an embodiment of a cross-section of the display panel corresponding to the lines X1-X1′ in FIG. 2.

FIG. 4 is an enlarged schematic cross-sectional view illustrating an example of area A of FIG. 3.

FIG. 5 is a schematic cross-sectional view illustrating a light emitting element according to an embodiment.

FIG. 6 is a schematic cross-sectional view illustrating a light emitting element according to an embodiment.

FIG. 7 is a schematic cross-sectional view illustrating a light emitting element according to an embodiment.

FIG. 8 is an enlarged schematic cross-sectional view illustrating an example of area A of FIG. 3 according to an embodiment.

FIG. 9 is a flowchart illustrating a method of manufacturing a display device according to an embodiment.

FIGS. 10 to 22 are drawings to illustrate a method of manufacturing a display panel according to an embodiment.

FIGS. 23 and 24 are drawings to illustrate an example in which a second element insulating layer is not formed in the flattening step of FIG. 9.

FIG. 25 is a block diagram of an electronic device according to one embodiment of the present disclosure.

FIG. 26 is a schematic diagram of an electronic device according to various embodiments of the present disclosure.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The expression “not overlap” may include a meaning such as “apart from” or “set aside from” or “offset from” and any other suitable equivalents as would be appreciated and understood by those of ordinary skill in the art.

The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, illustrative embodiments will be described with reference to the accompanying drawings.

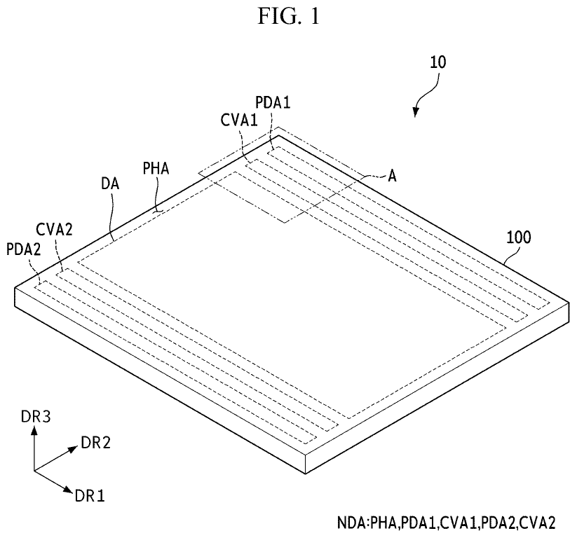

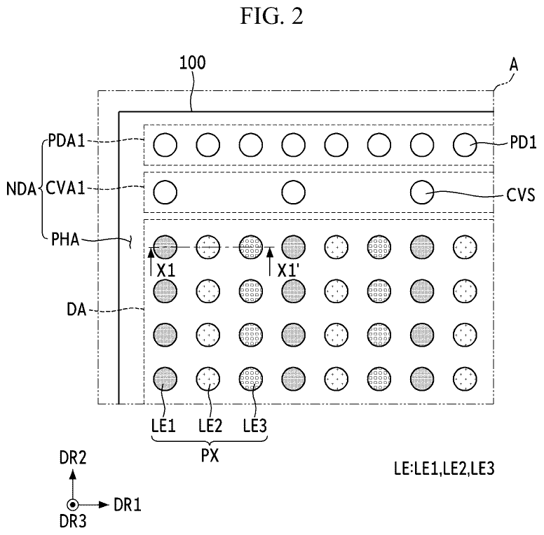

FIG. 1 is a schematic perspective view illustrating a display device according to an embodiment. FIG. 2 is a schematic plan view illustrating an embodiment of area A of FIG. 1.

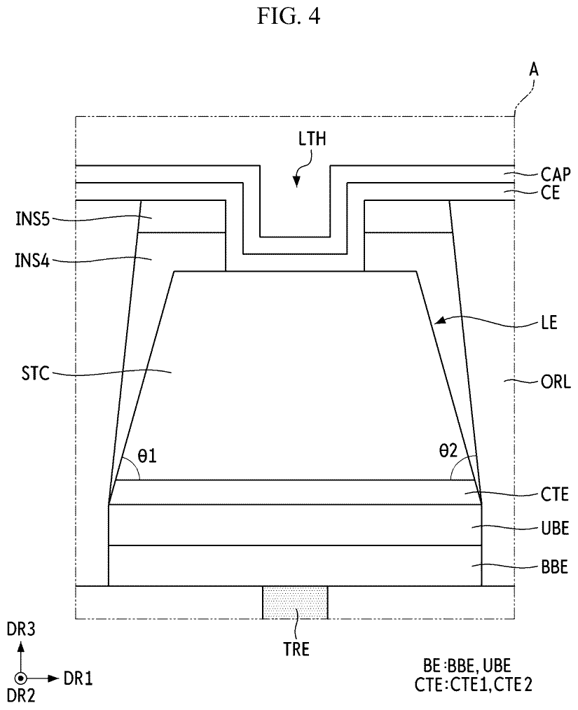

FIGS. 1 and 2 illustrate an embodiment in which the display device 10 is an LEDOS (Light Emitting Diode on Silicon) in which light emitting diodes are disposed as light emitting elements LE on a semiconductor circuit board formed by a semiconductor process using a silicon wafer (for example, a backplane substrate 110 of the display panel 100 on which a pixel circuit (PXC) or the like is formed based on a silicon wafer). However, devices including light emitting elements LE according to embodiments are not limited thereto. For example, the light emitting elements LE manufactured according to embodiments may be applied to display devices of different types and/or structures or may be applied to devices of different types and/or structures, such as lighting devices, etc. As one example, the embodiments described with reference to FIGS. 4 to 22 may also be applied to manufacturing devices of other types and/or structures including light emitting elements LE.

In FIGS. 1 and 2, the first direction DR1 may indicate a horizontal direction of the display panel 100, and the second direction DR2 may indicate a vertical direction of the display panel 100. The third direction DR3 may indicate a thickness direction of the display panel 100.

First, referring to FIGS. 1 and 2, the display device 10 according to an embodiment may include a display panel 100 including a display area DA and a non-display area NDA.

The display panel 100 may have a rectangular planar shape with a long side in the first direction DR1 and a short side in the second direction DR2. However, the planar shape of the display panel 100 is not limited to this, and the display panel 100 may have other shape. For example, the display panel 100 may have a polygonal, circular, elliptical, or other non-rectangular planar shape other than a rectangular shape.

The display area DA may be an area where an image is displayed, and the non-display area NDA may be an area where the image is not displayed. In an embodiment, the planar shape of the display area DA may follow the planar shape of the display panel 100. In FIG. 1, the planar shape of the display area DA is illustrated as a rectangle. The display area DA may be disposed in the central area of the display panel 100. The non-display area NDA may be disposed around the display area DA. In one example, the non-display area NDA may surround or may be adjacent to the display area DA.

The display area DA may include pixels PX. Each pixel PX may include at least two light emitting elements LE.

In an embodiment, each pixel PX may include three light emitting elements LE. For example, each pixel PX may include a first light emitting element LE1, a second light emitting element LE2, and a light emitting element LE3. The number and/or type of light emitting elements LE provided to the pixels PX may be varied in different embodiments.

In an embodiment, each pixel PX may include light emitting elements LE that emit light of different colors. For example, the first light emitting element LE1, the second light emitting element LE2, and the light emitting element LE3 may emit light of different colors.

The first light emitting element LE1 may emit a first light. The first light may be red light. For example, the main peak wavelength (R-peak) of the first light may be located in a range of about 600 nm to about 750 nm, but embodiments are not limited thereto.

The second light emitting element LE2 may emit a second light. The second light may be green light. For example, the main peak wavelength (G-peak) of the second light may be located in a range of about 480 nm to about 560 nm, but embodiments are not limited thereto.

The third light emitting element LE3 may emit a third light. The third light may be blue light. For example, the main peak wavelength (B-peak) of the third light may be located in a range of about 370 nm to about 460 nm, but embodiments are not limited thereto.

In an embodiment, the first light emitting element LE1, the second light emitting element LE2, and the light emitting element LE3 may emit light of the same color as each other. A light conversion layer including a light conversion element (for example, a quantum dot) for converting the color of light (or a wavelength band corresponding thereto) emitted from the at least one light emitting element LE into light of another color (or a wavelength band corresponding thereto) may be disposed on at least one light emitting element LE among the first light emitting element LE1, the second light emitting element LE2, and the light emitting element LE3, the color of light emitted from the at least one light emitting element LE.

In an embodiment, the first light emitting element LE1, the second light emitting element LE2, and the light emitting element LE3 of each pixel PX may be sequentially disposed in the first direction DR1. In an embodiment, the first light emitting elements LE1 may be arranged in the second direction DR2. The second light emitting elements LE2 may be arranged in the second direction DR2. The third light emitting elements LE3 may be arranged in the second direction DR2. For example, in each pixel column extending along the second direction DR2, the first light emitting element LE1, the second light emitting element LE2, or the third light emitting element LE3 may be arranged. The pixels PX, and the arrangement structure of the light emitting elements LE provided in the pixels PX, may be varied in different embodiments.

In an embodiment, the light emitting elements LE may be arranged in the display area DA at substantially equal intervals but is not limited thereto. For example, the positions and/or array spacing of the light emitting elements LE may be varied depending on the embodiments.

In an embodiment, the sizes (for example, areas) of the light emitting elements LE may be substantially the same as each other. For example, the first light emitting element LE1, the second light emitting element LE2, and the light emitting element LE3 may have substantially the same size. However, the embodiments are not limited to this, and the size of each light emitting element LE and/or the area of the light emitting areas corresponding to the light emitting elements LE may be varied in different embodiments.

In an embodiment, the light emitting elements LE may have a circular planar shape, but the embodiments are not limited thereto. For example, the light emitting elements LE may have a rectangular shape or another polygonal shape, an elliptical shape, or any other polygonal, elliptical, or irregular shape. Further, the light emitting elements LE may have substantially the same planar shape as each other or may have different planar shapes for each group.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connecting portions CVS connected to a common electrode. For example, the common electrode may extend from the display area DA to the first common voltage supply area CVA1 and the second common voltage supply area CVA2 and may be electrically connected to the common electrode connecting portions CVS. A common voltage may be supplied to the common electrode through common electrode connecting portions CVS.

The common electrode connecting portions CVS may be disposed in a common voltage supply area (for example, the first common voltage supply area CVA1 and/or the second common voltage supply area CVA2) of the non-display area NDA. The common electrode connecting portions CVS may include a conductive material (for example, a metal material such as aluminum (Al)). While FIGS. 1 and 2 illustrate the display device 10 in which the common electrode connecting portions CVS are disposed in the non-display area NDA, but the embodiments are not limited thereto. For example, the common electrode connecting portions CVS may be disposed in the display area DA. In one example, the common electrode connecting portions CVS may be disposed in pixel areas or between pixel areas.

The common electrode connecting portions CVS of the first common voltage supply area CVA1 may be electrically connected to one of the first pads PD1 of the first pad area PDA1. For example, the common electrode connecting portions CVS of the first common voltage supply area CVA1 may be supplied with a common voltage from one of the first pads PD1 of the first pad area PDA1.

The first pads PD1 may be disposed in the first pad area PDA1. The first pads PD1 may be connected to a circuit board (not shown) through a conductive connection member. For example, the first pads PD1 may be electrically connected to a circuit pad provided on a circuit board through wires.

The common electrode connecting portions CVS may also be disposed in the second common voltage supply area CVA2. The common electrode connecting portions CVS may be electrically connected to any one of the second pads of the second pad area PDA2. For example, the common electrode connecting portions CVS of the second common voltage supply area CVA2 may receive a common voltage from any one of the second pads of the second pad area PDA2. In an embodiment, the display panel 100 may not include the second common voltage supply area CVA2.

The first pad area PDA1 may be disposed on one side or a side (for example, the upper side) of the display panel 100. The first pad area PDA1 may include first pads PD1 connected to an external circuit board.

The second pad area PDA2 may be disposed on another side (for example, the lower side) of the display panel 100. The second pad area PDA2 may include second pads connected to an external circuit board. In an embodiment, the display panel 100 may not include the second pad area PDA2.

The second pads may be disposed in the second pad area PDA2 of the non-display area NDA. The second pads may be connected to the circuit board (not shown) through a conductive connection member. For example, the second pads may be electrically connected to circuit pads provided on the circuit board through wires.

The peripheral area PHA may be the non-display area NDA excluding the first common voltage supply area CVA1, the second common voltage supply area CVA2, the first pad area PDA1, and the second pad area PDA2. The peripheral area PHA may surround the display area DA, as well as the first common voltage supply area CVA1, the second common voltage supply area CVA2, the first pad area PDA1, and the second pad area PDA2.

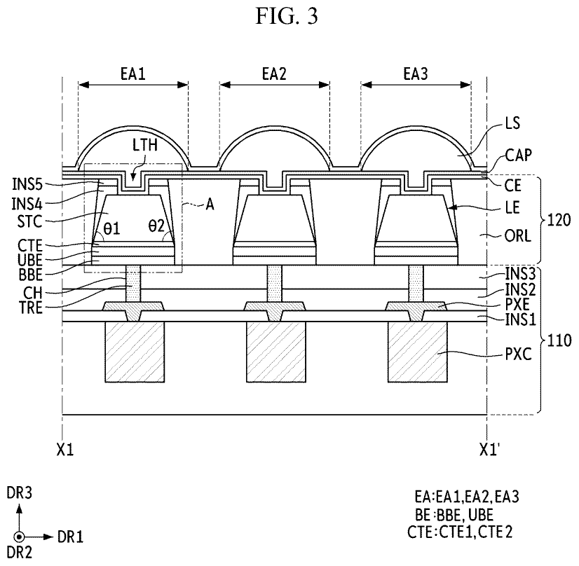

FIG. 3 is a schematic cross-sectional view illustrating an embodiment of a cross-section of the display panel corresponding to the lines X1-X1′ in FIG. 2. FIG. 4 is an enlarged schematic cross-sectional view illustrating an example of area A of FIG. 3.

Referring to FIG. 3, the display panel (100 in FIG. 2) may include a backplane substrate 110 and a light emitting element layer 120. In an embodiment, the display panel 100 may further include an optical structure or member (or light emitting structure) provided on the light emitting element layer 120, for example, a lens-type optical structure LS.

The display panel 100 may further include additional components according to embodiments. For example, the display panel 100 may further include a light conversion layer for converting the color and/or wavelength of light emitted from at least some of the light emitting elements LE, and/or a color filter layer for controlling that light of a given color is emitted from each of the light emitting area EA.

The display panel 100 may include light emitting areas EA located in the display area DA. Each of the light emitting areas EA may include at least one light emitting element LE. For example, the light emitting areas EA may include a first light emitting area EA1 provided with at least one first light emitting element LE1 and a second light emitting area EA2 provided with at least one second light emitting element LE2, and a third light emitting area EA3 provided with at least one third light emitting element LE3. In an embodiment, first light, second light, and third light may be emitted from the first light emitting area EA1, the second light emitting area EA2, and the third light emitting area EA3, respectively.

The backplane substrate 110 may include a display area DA including light emitting areas EA. In an embodiment, the backplane substrate 110 may be a semiconductor circuit board formed through a semiconductor process using a silicon wafer. For example, a silicon wafer may be used as a base member to form the display panel 100.

The backplane substrate 110 may include pixel circuits PXC, pixel electrodes PXE and interlayer insulating layers INS1, INS2, and INS3 provided in the display area DA. For example, at least one light emitting element LE may be provided in each light emitting area EA of the display panel 100, and the backplane substrate 110 may include pixel circuits PXC and pixel electrodes PXE electrically connected to each of the light emitting elements LE disposed in each of the light emitting areas EA. The pixel electrodes PXE may be omitted, and in case that the pixel electrodes PXE are omitted, the connection electrode BE may be directly connected to the pixel circuits PXC by through-hole electrode TRE.

The pixel circuits PXC may be provided in the display area DA corresponding to the area where each pixel PX and/or the light emitting areas EA are formed. In an embodiment, each of the pixel circuits PXC may include a complementary metal-oxide semiconductor (CMOS) circuit formed using a semiconductor process.

Each of the pixel circuits PXC may include at least one transistor formed through a semiconductor process. Each of the pixel circuits PXC may further include at least one capacitor formed through a semiconductor process.

In an embodiment, a circuit insulation layer INS1 may be disposed on the pixel circuits PXC. The circuit insulation layer INS1 may be made of an inorganic film, such as a silicon nitride layer, a silicon oxynitride layer, a silicon oxide layer, a titanium oxide layer, or an aluminum oxide layer.

The pixel electrodes PXE may be disposed on the circuit insulation layer INS1. The pixel electrodes PXE may be connected to the pixel circuits PXC through a contact hole penetrating the circuit insulation layer INS1. Each of the pixel electrodes PXE may be electrically connected to the pixel circuits PXC. For example, the pixel electrodes PXE and the pixel circuits PXC may be connected in a one-to-one correspondence but are not limited thereto. Each of the pixel circuits PXC may apply a pixel voltage to a pixel electrode PXE connected thereto. Each of the pixel electrodes PXE may receive a pixel voltage from the pixel circuit PXC. The pixel electrodes PXE may include a conductive material (for example, a metal material such as aluminum (Al)).

One or more interlayer insulating layers INS2 and INS3 may be disposed on the pixel electrodes PXE. In an embodiment, the interlayer insulating layers INS2 and INS3 may include a first interlayer insulating layer INS2 and a second interlayer insulating layer INS3.

The second interlayer insulating layer INS3 may be disposed on the first interlayer insulating layer INS2.

The first interlayer insulating layer INS2 and the second interlayer insulating layer INS3 may be formed of a same material but are not limited thereto. The first interlayer insulating layer INS2 and the second interlayer insulating layer INS3 may be formed of an inorganic film, such as a silicon nitride layer, a silicon oxynitride layer, a silicon oxide layer, a titanium oxide layer, or an aluminum oxide layer.

A through-hole electrode TRE may be disposed in a contact hole CH through which the first interlayer insulating layer INS2 and the second interlayer insulating layer INS3 penetrate to electrically connect the connection electrode BE and the pixel circuits PXC. For example, the through-hole electrode TRE may be disposed to fill the contact hole CH and may directly contact the pixel electrode PXE exposed by the contact hole CH.

The through-hole electrode TRE may include a conductive material. In an embodiment, the through-hole electrode TRE may be a metal material such as copper (Cu) but is not limited thereto.

The backplane substrate 110 may further include a non-display area NDA as shown in FIGS. 1 and 2. In an embodiment, the backplane substrate 110 may further include the common electrode connecting portions CVS, the first pads PD1, and/or the second pads, etc., located in the non-display area NDA.

The light emitting element layer 120 may include a connection electrode BE, light emitting elements LE, insulating layers INS4 and INS5, and a common electrode CE. In an embodiment, the light emitting element layer 120 may further include an organic layer ORL disposed around the light emitting elements LE, and/or a capping layer CAP disposed on the common electrode CE. Here, the insulating layers INS4 and INS5 will be referred to as element insulating layers for clear distinction from the interlayer insulating layers INS2 and INS3 described above.

In an embodiment, the light emitting element layer 120 may further include additional components. For example, the light emitting element layer 120 may further include a reflective layer and/or a light blocking layer provided between the light emitting elements LE and/or on the sides of the light emitting elements LE.

The connection electrode BE may include a first connection electrode BBE and a second connection electrode UBE that are sequentially stacked.

The first connection electrode BBE may be disposed on the second interlayer insulating layer INS3 and the through-hole electrode TRE. The first connection electrode BBE may be connected to the pixel electrode PXE through the through-hole electrode TRE.

The second connection electrode UBE may be disposed on the first connection electrode BBE.

The first connection electrode BBE and the second connection electrode UBE may include a single layer of conductive material or may be formed as a multilayer. The conductive material may include Ti, Ni, Pt, Sn, Au, Al, and W. For example, the first connection electrode BBE and the second connection electrode UBE may include a barrier layer formed of titanium (Ti) and a connection layer formed of gold (Au) having a low melting point.

The second connection electrode UBE may include three electrode layers. For example, the upper connection electrode UBE may include a first electrode layer formed of Sn, a second electrode layer formed of Au, and a third electrode layer formed of Ti.

In case that the first connection electrode BBE and the second connection electrode UBE include connection layers, the connection layer of the first connection electrode BBE and the connection layer of the second connection electrode UBE may be arranged to face each other.

The light emitting element LE may be disposed on the second connection electrode UBE.

One end of the light emitting element LE may be electrically connected to the pixel electrodes PXE through the connection electrode BE. The other end of the light emitting element LE may be electrically connected to the common electrode.

The pixel electrodes PXE may be connected to each pixel circuit PXC. The pixel electrodes PXE may be individually provided in each of the light emitting areas EA and may be electrically connected to the light emitting elements LE positioned in each of the light emitting areas EA. Accordingly, the light emitting elements LE disposed in each of the light emitting areas EA may be individually and/or independently controlled.

Each of the light emitting elements LE may be positioned on the connection electrode BE. The light emitting elements LE may be vertical light emitting diode elements extending in the third direction DR3. For example, the length of the light emitting element LE in the third direction DR3 may be longer than the length in the horizontal direction. The length in the horizontal direction refers to the length in the first direction DR1 or the length in the second direction DR2.

The light emitting elements LE may be micro light emitting diode elements or nano light emitting diode elements.

The light emitting elements LE may include a semiconductor stack grown on a semiconductor substrate (for example, a wafer substrate) by epitaxial growth. For example, the semiconductor stack may include a first semiconductor layer doped with a first conductivity type, a second semiconductor layer doped with a second conductivity type, and an active layer disposed between the first semiconductor layer and the second semiconductor layer.

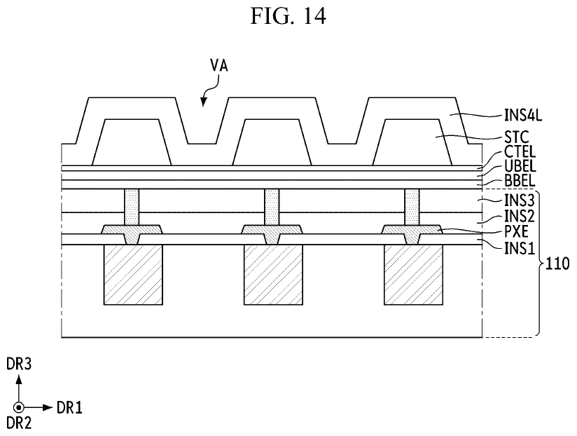

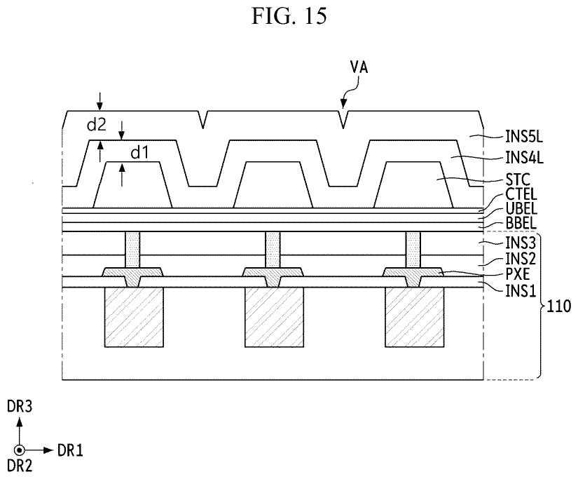

In an embodiment, insulating layers may be disposed on the upper surface of the light emitting element LE. For example, a first element insulating layer INS4 (INS4L of FIGS. 14-18, 23, 24) and a second element insulating layer INS5 (INS5L of FIGS. 15-22) may be disposed on the top surface of the light emitting element LE.

The first element insulating layer INS4 may cover the top surface and the side surface of the light emitting element LE. The first element insulating layer INS4 does not surround the side surface of the connection electrode BE. The first element insulating layer INS4 may be formed to become thicker from the bottom to the top of the light emitting element LE. For example, the inclined surface of the light emitting element LE may have a first acute angle θ1. The inclined surface may be an angle formed by the side surface of the light emitting element LE and the bottom surface of the light emitting element LE. The slope of the first element insulating layer INS4 may have a second acute angle θ2. The second acute angle θ2 may be a larger angle than the first acute angle θ1. The slope of the first element insulating layer INS4 may be an angle formed by a surface parallel to the bottom surface of the light emitting element LE and a surface where the first element insulating layer INS4 meets.

The slope of the first element insulating layer INS4 may become thicker as it goes toward the upper portion of the light emitting element LE. For example, the slope of the first element insulating layer INS4 may become thicker as it goes from the connection electrode UBE and BBE toward the common electrode CE.

The side surfaces of the first element insulating layer INS4, the second connection electrode UBE, and the first connection electrode BBE may be aligned with each other and arranged in a straight line.

As described above, the second element insulating layer INS5 covers the top of the light emitting element LE on the first element insulating layer INS4.

In a planar view, the diameter of the second element insulating layer INS5 may be equal to or less than the diameter of the first element insulating layer INS4. The diameter of the first element insulating layer INS4 may be equal to or larger than the diameter of the light emitting element LE.

The first and second element insulating layers INS4 and INS5 may be formed of a same material but are not limited thereto. The first and second element insulating layers INS4 and INS5 may be formed of an inorganic film, such as silica, silicon nitride layer, silicon oxynitride layer, silicon oxide layer, titanium oxide layer, or aluminum oxide layer.

The top surface of the light emitting element LE may be exposed at least in part by a through hole LTH penetrating the first and second element insulating layers INS4 and INS5.

In an embodiment, a reflective layer may be further disposed on the side of the first element insulating layer INS4. The reflective layer serves to reflect light emitted from the light emitting element LE that travels in the up, down, left, and right lateral directions rather than the upper direction. The reflective layer may include a metal material with high reflectivity, such as aluminum (Al).

An organic layer ORL may be provided around the light emitting elements LE. For example, the organic layer ORL may be disposed between the light emitting areas EA to surround the light emitting areas EA where the light emitting elements LE are provided and may surround the light emitting elements LE and the connection electrodes BBE and UBE. In an embodiment, the organic layer ORL may be a filler that fills the gap between the light emitting elements LE. The organic layer ORL may expose a portion of the light emitting elements LE, for example, the top surface.

The organic layer ORL may include an insulating material. For example, the organic layer ORL may be a single layer or multiple layers of an organic insulating film including an acrylic resin, epoxy resin, phenolic resin, polyamide resin, polyimide resin, or other organic insulating material.

The common electrode CE may be disposed on top of the light emitting elements LE that are not covered by the organic layer ORL. The common electrode CE may contact the light emitting element LE through the through hole LTH penetrating the first and second element insulating layers INS4 and INS5.

In an embodiment, the common electrode CE may be entirely disposed in the display area DA to cover the light emitting elements LE and the organic layer ORL. The common electrode CE may be a common layer commonly formed and/or connected to the light emitting elements LE and the pixels PX including them in the display area DA.

The common electrode CE may be electrically connected to the common electrode connecting portions CVS disposed in the first common voltage supply area CVA1 and/or the second common voltage supply area CVA2 of FIGS. 1 and 2. Accordingly, the common electrode CE may be supplied with the common voltage through the common electrode connecting portions CVS.

The common electrode CE may include a transparent conductive material capable of transmitting light. For example, the common electrode CE may be made of indium tin oxide (ITO), indium zinc oxide (IZO), or other transparent conductive materials. In an embodiment, it may function as a cathode electrode (or anode electrode) of the light emitting elements LE.

The capping layer CAP may be disposed on the common electrode CE. For example, the capping layer CAP may be disposed over the entire display area DA to cover the common electrode CE. The capping layer CAP may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or other insulating material.

In an embodiment, the display panel 100 may include a lens-type optical structure LS provided on the light emitting element layer 120. The display panel 100 may further include a protective layer PSV covering the lens-type optical structure LS.

The lens-type optical structure LS may be disposed in each light emitting area EA to overlap the light emitting elements LE. In an embodiment, the lens-type optical structure LS may be an optical structure in the form of a convex lens provided on top of the light emitting elements LE, but the type and/or shape of the optical structure is not limited thereto. By disposing the lens-type optical structure LS on top of the light emitting elements LE, the light output characteristics of the pixels PX may be adjusted and/or improved.

The lens-type optical structure LS may be formed of a transparent material to allow light incident from the light emitting elements LE to be transmitted. For example, the lens-type optical structure LS may be formed of glass, plastic, ceramic, or other materials, and may be formed of an optical material with a high refractive index.

The protective layer PSV may be disposed on the lens-type optical structure LS to cover the lens-type optical structure LS. The protective layer PSV may be formed of a transparent and durable material (for example, plastic or organic glass, optical glass, ceramic, etc.), but is not particularly limited thereto, as long as the material is suitable for protecting the lens-type optical structure LS. Although FIG. 3 illustrates an embodiment in which the protective layer PSV has a curve corresponding to the shape of the lens-type optical structure LS, the embodiments are not limited thereto. For example, the protective layer PSV may be formed in a shape that may planarize the top surface of the display panel 100 on which the lens-type optical structure LS is formed.

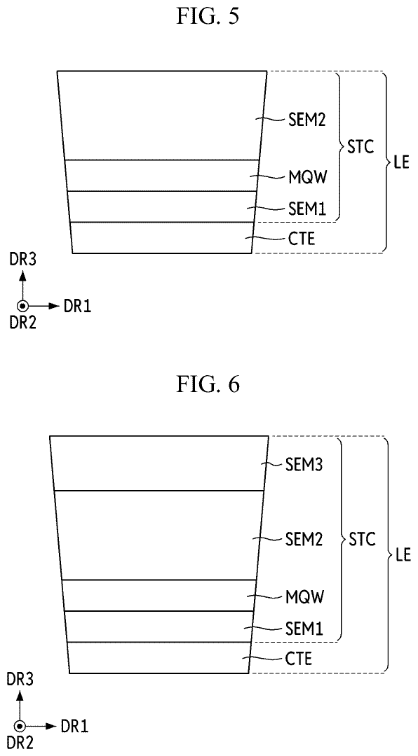

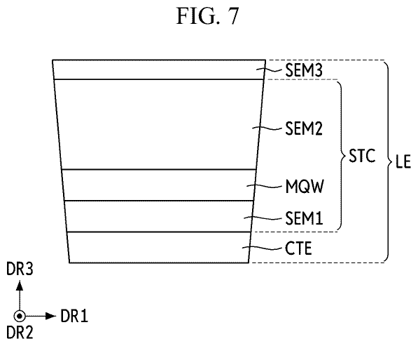

FIG. 5 is a schematic cross-sectional view illustrating a light emitting element according to an embodiment. FIG. 6 is a schematic cross-sectional view illustrating a light emitting element according to an embodiment. FIG. 7 is a schematic cross-sectional view illustrating a light emitting element according to an embodiment.

Referring to FIGS. 5 and 6, the light emitting element LE may include a semiconductor stack STC and a contact electrode CTE disposed at one end of the semiconductor stack STC. Referring to FIG. 6, the light emitting element LE may include a first contact electrode CTE1 and a second contact electrode CTE2 disposed at both ends of the semiconductor stack STC.

The contact electrode CTE may be provided and/or formed at one end or an end of the semiconductor stack STC on which (for example, the first semiconductor layer SEM1) is disposed. For example, the contact electrode CTE may be provided and/or formed on one surface or a surface of the first semiconductor layer SEM1. The contact electrode CTE may be an electrode for protecting the first semiconductor layer SEM1 and smoothly connecting the first semiconductor layer SEM1 to at least one circuit element, electrode, wiring, and/or conductive layer. The contact electrode CTE may include a metal, a metal oxide, or other conductive material.

As shown in FIG. 6, in case that a first contact electrode CTE1 and a second contact electrode CTE2 are disposed at both ends of a semiconductor stack STC, the first contact electrode CTE1 may be disposed on a bottom surface of the semiconductor stack STC, and the second contact electrode CTE2 may be disposed on a top surface of the semiconductor stack STC. The first contact electrode CTE1 and the second contact electrode CTE2 may be a same material but are not limited thereto. The first contact electrode CTE1 and the second contact electrode CTE2 may include a metal, a metal oxide, or other conductive material.

The semiconductor stack STC may include a first semiconductor layer SEM1, an active layer MQW, and a second semiconductor layer SEM2 that are sequentially disposed and/or laminated along the third direction as shown in FIG. 5. For example, the first semiconductor layer SEM1 may be disposed on a first contact electrode CTE1.

The semiconductor stack STC may be variously modified according to embodiments. For example, the semiconductor stack STC may further include a third semiconductor layer SEM3, as shown in FIG. 6. The third semiconductor layer SEM3 may be disposed on the second semiconductor layer SEM2.

The light emitting element LE may further include additional layers depending on embodiments. For example, the light emitting element LE may further include an electron blocking layer disposed between the first semiconductor layer SEM1 and the active layer MQW, and/or a superlattice layer disposed between the active layer MQW and the second semiconductor layer SEM2.

In an embodiment, the light emitting element LE may be an inorganic light emitting element made of an inorganic material. For example, the light emitting element LE may be an inorganic light emitting diode formed from a nitride-based semiconductor material such as GaN, AlGaN, InGaN, AlInGaN, AlN or InN, a phosphide-based semiconductor material such as GaP, GaInP, AlGaP, AlGaInP, AlP or InP, or any other inorganic material.

The contact electrode CTE may be provided and/or formed at one end or an end of the light emitting element LE where the first semiconductor layer SEM1 is disposed. For example, the contact electrode CTE may be provided and/or formed on one surface or a surface of the first semiconductor layer SEM1. The contact electrode CTE may be an electrode that protects the first semiconductor layer SEM1 and smoothly connects the first semiconductor layer SEM1 to at least one circuit element, electrode, wiring, and/or conductive layer. The contact electrode CTE may include a metal, metal oxide, or other conductive material.

The first semiconductor layer SEM1 may be disposed on the contact electrode CTE. In an embodiment, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SEM1 may include other materials.

The first semiconductor layer SEM1 may include a semiconductor material doped with a first conductivity type dopant. For example, the first semiconductor layer SEM1 may include GaN (for example, p-type dopant) doped with a first conductive dopant (for example, p-type dopant) such as Mg, Zn, Ca, Se, Ba, or the like within the spirit and the scope of the disclosure.

The active layer MQW may be disposed on the first semiconductor layer SEM1.

The active layer MQW may emit light by recombination of electron-hole pairs according to an electrical signal applied through the first semiconductor layer SEM1 and the second semiconductor layer SEM2. For example, the active layer MQW may be a light emitting layer of the light emitting element LE.

The active layer MQW may include a material with a single or multiple quantum well structure. In case that the active layer MQW may include a material with a multi-quantum well structure, the active layer MQW may have a structure in which well layers and barrier layers are alternately stacked with each other. The active layer MQW may include three to five different semiconductor materials, depending on the wavelength band of the light emitted.

In an embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, the well layer may be formed of InGaN, and the barrier layer may be formed of GaN or AlGaN, but embodiments are not limited thereto. In case that the active layer MQW may include InGaN, the color of light emitted from the light emitting element LE may be controlled by adjusting the content of indium (In). The active layer MQW may also include other materials.

In an embodiment, the active layers MQW of the first light emitting element LE1, the second light emitting element LE2, and the third light emitting element LE3 shown in FIGS. 2 and 3 may emit light of the same color (for example, blue light) as each other. In an embodiment, the active layers MQW of the first light emitting element LE1, the second light emitting element LE2, and the third light emitting element LE3 may emit different colors of light (for example, red light, green light, and blue light, respectively).

The second semiconductor layer SEM2 may be disposed on the active layer MQW.

In an embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SEM2 may also include other materials.

The second semiconductor layer SEM2 may include a semiconductor material doped with a second conductivity type dopant. For example, the second semiconductor layer SEM2 may include GaN (for example, n-GaN) doped with a second conductive dopant (for example, n-type dopant), such as Si, Ge, Sn, or the like within the spirit and the scope of the disclosure.

In an embodiment, the first semiconductor layer SEM1 and the second semiconductor layer SEM2 may have different thicknesses in a thickness direction of the light emitting element LE (for example, the third direction DR3). For example, the second semiconductor layer SEM2 may have a larger thickness than the first semiconductor layer SEM1 in the thickness direction of the light emitting element LE. Accordingly, the active layer MQW may be located closer to a first end (for example, a p-type end) of the light emitting element LE provided with the first semiconductor layer SEM1 than to a second end (for example, an n-type end) of the light emitting element LE provided with the second semiconductor layer SEM2.

In an embodiment, the light emitting element LE may be a vertical micro-LED extending and/or stacked in the third direction DR3. For example, the light emitting element LE may be a micro-LED having a length in the first direction DR1, a length in the second direction DR2, and a length in the third direction DR3 of tens to hundreds of micrometers (μm), respectively. In an embodiment, the length of the light emitting element LE in the first direction DR1, the length in the second direction DR2, and the length in the third direction DR3 may each be about 100 μm or less.

In an embodiment, the light emitting element LE may have a cross-sectional shape of an inverted taper. For example, the light emitting element LE may have a cross-sectional shape of an inverted trapezoid, in which the width of the top surface is wider than the width of the bottom surface.

In an embodiment, the light emitting element LE may be disposed on the backplane substrate 110 such that the first semiconductor layer SEM1 is located below the active layer MQW and the second semiconductor layer SEM2 is located above the active layer MQW, as shown in FIG. 5. For example, the light emitting element LE may be disposed in each light emitting area EA such that the contact electrode CTE (or the first semiconductor layer SEM1) is in contact with the connection electrode BE of FIG. 3 and the second semiconductor layer SEM2 is in contact with the common electrode CE. The common electrode CE may be a cathode electrode.

As shown in FIG. 6, in case that the light emitting element LE may include a third semiconductor layer SEM3, the third semiconductor layer SEM3 may be disposed on the second semiconductor layer SEM2, and the third semiconductor layer SEM3 may be in contact with the common electrode CE.

The third semiconductor layer SEM3 may be a semiconductor material layer having an n-type dopant lower than a selectable threshold value and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN) having an n-type dopant lower than a selectable threshold value.

As shown in FIG. 7, in case that the light emitting element LE is disposed with the first contact electrode CTE1 and the second contact electrode CTE2 on both ends of the semiconductor stack STC, the first contact electrode CTE1 may be disposed under or below the first semiconductor layer SEM1, and the second contact electrode CTE2 may be disposed on the second semiconductor layer SEM2. In case that the light emitting element LE may further include the third semiconductor layer SEM3, the second contact electrode CTE2 may be disposed on the third semiconductor layer SEM3.

In case that the second contact electrode CTE2 is disposed between the semiconductor stack STC and the light emitting element LE, the current may be evenly spread over the entire surface of the light emitting element LE. Therefore, the second contact electrode CTE2 at this time may be referred to as a current spreading layer.

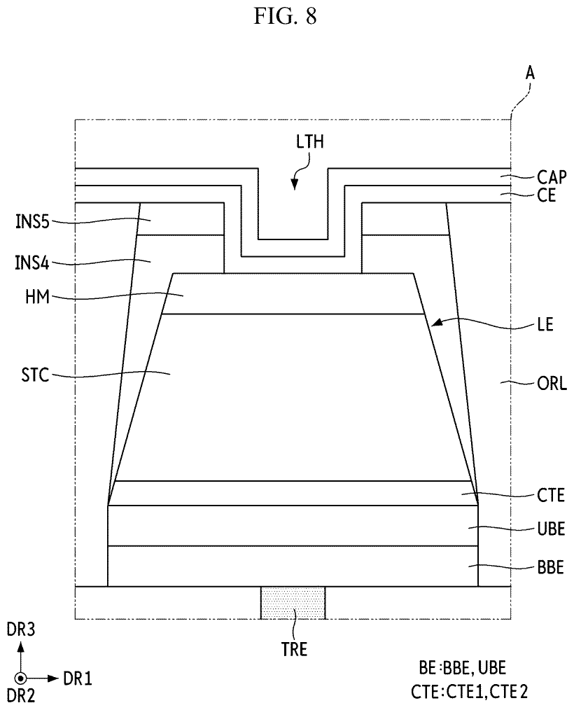

FIG. 8 is an enlarged schematic cross-sectional view illustrating an example of area A of FIG. 3 according to an embodiment.

FIG. 8 may be different from the embodiment of FIG. 4 in that a mask pattern HM may be further disposed between the first element insulating layer INS4 and the light emitting element LE. In the embodiment of FIG. 8, descriptions that overlap with those of the embodiment of FIG. 4 will not be repeated.

The mask pattern HM between the first element insulating layer INS4 and the light emitting element LE may be referred to as a mask pattern HM in that it is used as a mask in the process.

The mask pattern HM may be formed of silicon oxide but is not limited thereto.

The mask pattern HM may be disposed on the top surface of the semiconductor stack STC and may not be disposed on the side surface of the semiconductor stack STC. For example, in a semiconductor stack STC as shown in FIG. 5, the mask pattern HM may be disposed on the second semiconductor layer SEM2. In a semiconductor stack STC shown in FIG. 6, it may be disposed on the third semiconductor layer SEM3. Further, in a semiconductor stack STC as shown in FIG. 7, it may be disposed on a second contact electrode CTE2.

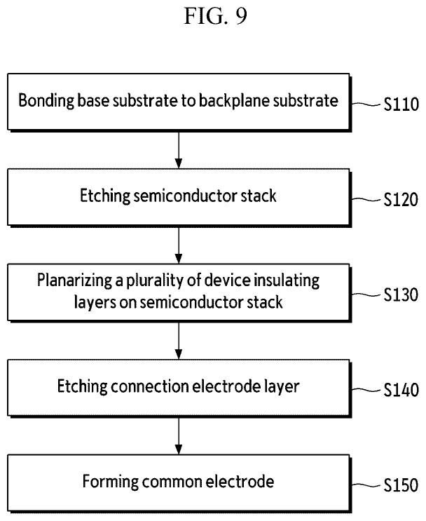

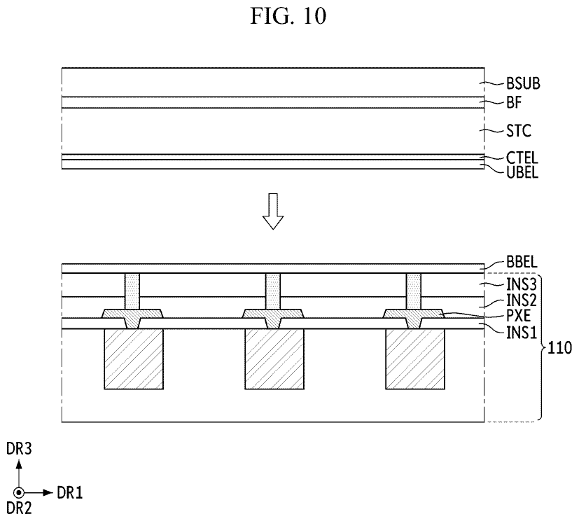

FIG. 9 is a flowchart illustrating a method of manufacturing a display device according to an embodiment. FIGS. 10 to 22 are drawings to illustrate a method of manufacturing a display panel according to an embodiment. For example, each of FIGS. 9 to 25 illustrates, in the form of a schematic cross-sectional view, a given step for forming a display panel 100.

A base substrate BSUB is bonded to a backplane substrate 110. (S110 of FIG. 9)

Referring to FIG. 10, a first connection electrode layer BBEL is formed on a top portion of the backplane substrate 110, and an upper connection electrode layer UBEL is formed on the base substrate BSUB on which a multi-layer semiconductor stack STC is laminated.

For example, a conductive first connection electrode layer BBEL may be formed by applying a conductive bonding material to the entire top surface of the backplane substrate 110. The first connection electrode layer BBEL may be formed as a multilayer.

A buffer layer BF may be formed on one surface or a surface of the base substrate BSUB. The base substrate BSUB may be a substrate including a material such as silicon (Si), sapphire, SiC, GaN, GaAs, or ZnO. In case that the epitaxial growth for manufacturing the light emitting element LE may be smoothly performed, the type, material, and shape of the base substrate BSUB are not particularly limited.

A multi-layer semiconductor stack STC may be disposed on the buffer layer BF. The multi-layer semiconductor stack STC may include a first semiconductor layer SEM1, an active layer MQW, a second semiconductor layer SEM2, and a third semiconductor layer SEM3, as shown in FIG. 6.

For example, as shown in FIG. 6, a third semiconductor layer SEM3, a second semiconductor layer SEM2, an active layer MQW, and a first semiconductor layer SEM1 may be sequentially formed through epitaxial growth on the base substrate BSUB. In an embodiment, the third semiconductor layer SEM3, the second semiconductor layer SEM2, the active layer MQW, and the first semiconductor layer SEM1 may be formed by epitaxial growth using a process technology such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

In an embodiment, in case that manufacturing a light emitting element LE including a contact electrode CTE as in the embodiments of FIG. 6, a process of forming a contact electrode CTE (or a conductive layer for forming the contact electrode layer CTEL) on the multi-layer semiconductor stack STC may be additionally performed. The contact electrode CTE may be formed of a material of the contact electrode CTE described above. The contact electrode CTE may be formed through a process such as applying (for example, depositing) a conductive material on the semiconductor stack STC, and the method of forming the contact electrode CTE is not particularly limited.

One or more layers of second connection electrode material may be formed on the top surface of the semiconductor stack STC (or the contact electrode CTE).

For example, the conductive second connection electrode layer UBEL is formed by applying a conductive bonding material that has a second connection electrode material applied to the top surface of the semiconductor stack STC or the contact electrode CTE.

The second connection electrode layer UBEL of the base substrate BSUB is placed to face the first connection electrode layer BBEL of the backplane substrate 110. Thereafter, the base substrate BSUB may be bonded by placing it on the backplane substrate 110 so that the first connection electrode layer BBEL of the backplane substrate 110 and the second connection electrode layer UBEL of the base substrate BSUB are in contact with each other. Accordingly, the semiconductor stack STC of the base substrate BSUB may be bonded on the backplane substrate 110.

In an embodiment, the first connection electrode layer BBEL of the backplane substrate 110 and the second connection electrode layer UBEL of the base substrate BSUB may be bonded by bonding the base substrate BSUB to the backplane substrate 110 by a thermal compression (TC) bonding method. The bonding (or adhesion) method of the base substrate BSUB to the backplane substrate 110 is not limited thereto, and the backplane substrate 110 and the base substrate BSUB may be bonded by other methods.

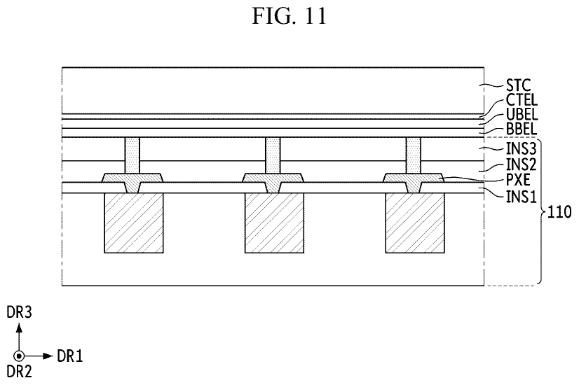

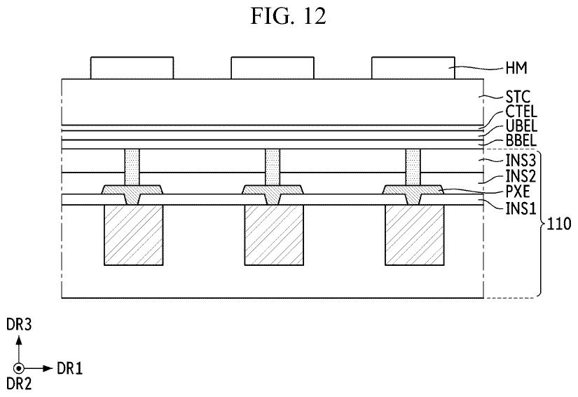

As shown in FIG. 11, the base substrate BSUB may be removed.

For example, a laser beam is irradiated to the base substrate BSUB using a laser device to separate the multi-layer semiconductor stack STC from the base substrate BSUB. The base substrate BSUB is separated from the third semiconductor layer SEM3 of the multi-layer semiconductor stack STC.

The process of separating the base substrate BSUB may be separated by the laser lift off (LLO) process. The laser lift off process is performed by using a laser. As a source, a KrF excimer laser (about 248 nm wavelength) may be used but is not limited thereto. By irradiating the base substrate BSUB with a laser, the base substrate BSUB may be separated from the multi-layer semiconductor stack STC.

In some instances, the buffer layer BF and the third semiconductor layer SEM3 may be removed through a polishing process such as a chemical mechanical polishing (CMP) process and/or an etching process. Further, the third semiconductor layer SEM3 of the semiconductor stack STC may be removed through a polishing process such as a CMP process. At this time, if desirable, at least a portion of the third semiconductor layer SEM3 of the semiconductor stack STC may be left (see FIG. 6).

The semiconductor stack STC may be etched using a mask. (S120 of FIG. 9)

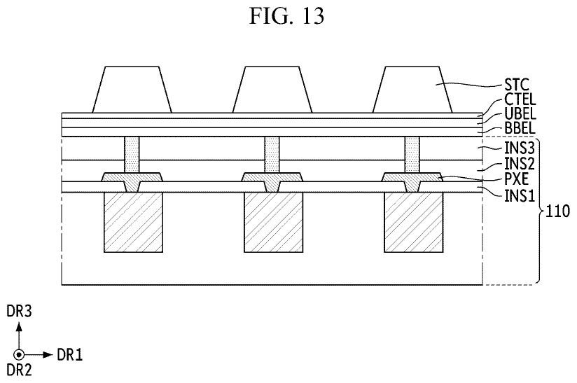

As shown in FIGS. 12 and 13, a mask pattern HM may be formed on the top surface of the semiconductor stack STC. The mask pattern HM may be disposed in an area where the light emitting element LE is to be formed. The mask pattern HM may be formed of an insulating material such as silicon oxide.

The mask pattern HM is a material that is not etched by an etching material for etching the semiconductor stack STC. The mask pattern HM may be formed of an insulating material such as silicon oxide.

The semiconductor stack STC may be etched using the mask pattern (HM of FIG. 12).

For example, the semiconductor stack STC overlapping the mask pattern HM may not be etched, and the semiconductor stack STC that does not overlap the mask may be etched.

In FIG. 13, it is described that the mask pattern HM is completely etched and removed, but this is not limited thereto. For example, the mask pattern HM may remain on the top surface of the semiconductor stack STC (see the light emitting element LE of FIG. 8).

Multiple element insulating layers INS4 and INS5 may be formed and planarized. (S130 of FIG. 9)

As shown in FIG. 14, the first element insulating layer INS4 may be formed by applying an insulating material to the entire surface of the backplane substrate 110 on which semiconductor stacks STC are etched. The first element insulating layer INS4 may be applied to surround both the side surfaces and the top surfaces of the semiconductor stacks STC. The first element insulating layer INS4 may be formed with the same thickness on the lower structure. Therefore, a valley VA may be formed between the semiconductor stacks STC and the semiconductor stacks STC.

As shown in FIG. 15, an insulating material may be applied to the entire surface of the backplane substrate 110 to completely cover the first element insulating layer INS4. Furthermore, in the valley VA formed between the semiconductor stacks STC and the semiconductor stacks STC, the thickness d2 of the second element insulating layer INS5 may be formed to be at least thicker than the thickness d1 of the first element insulating layer INS4 formed on the top portion of the light emitting element LE.

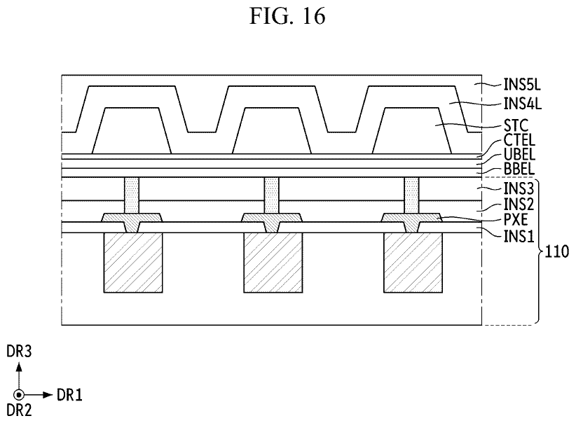

Thereafter, as shown in FIG. 16, the top portion of the second element insulating layer INS5 may be planarized through a polishing process such as a CMP process and/or an etching process. Through this process, the step formed by the semiconductor stacks STC may be planarized.

After the planarization, the thickness of the second element insulating layer INS5 may be thinner than the thickness of the first element insulating layer INS4.

The first connection electrode layer BBEL and the second connection electrode layer UBEL are etched. (S140 of FIG. 9)

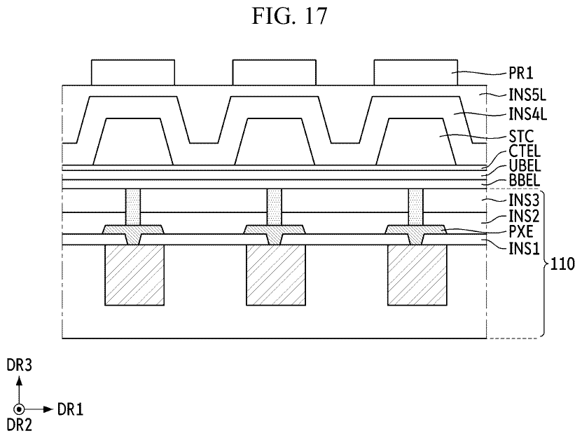

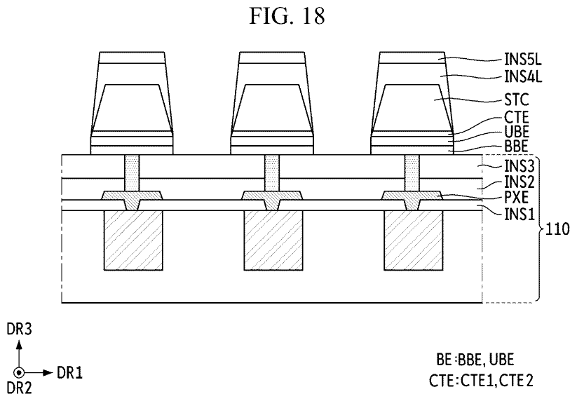

For example, referring to FIG. 17 and FIG. 18, a photoresist PR1 pattern may be formed as a mask on element insulating layers INS4 and INS5 to etch the first connection electrode layer BBEL and the second connection electrode layer UBEL. The process of etching the first connection electrode layer BBEL and the second connection electrode layer UBEL may be similar to the process of etching the semiconductor stack. Accordingly, the side surfaces of the first connection electrode BBE and the second connection electrode UBE formed in this manner and the side surfaces of the fourth element insulating layer INS4 may be mutually aligned and disposed in a straight line.

Thereafter, a subsequent process including a process of forming a common electrode CE, etc. may be performed. (S150 of FIG. 9)

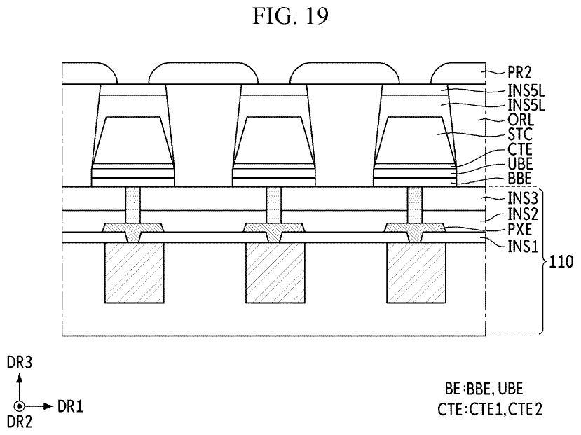

Referring to FIG. 19, an organic layer ORL may be formed between the light emitting elements LE.

For example, a filler FIL may be applied between the light emitting elements LE to fill the organic layer ORL between the light emitting elements LE.

A through hole LTH may be formed in the first element insulating layer INS4 and the second element insulating layer INS5 on the semiconductor stack STC using a photoresist mask PR2 to expose the top surface of the light emitting element LE.

In an embodiment, the photoresist mask PR2 may be a positive photoresist pattern.

The photoresist mask PR2 may be disposed not to overlap the light emitting area. The photoresist PR1 pattern may be disposed to overlap the non-emitting area.

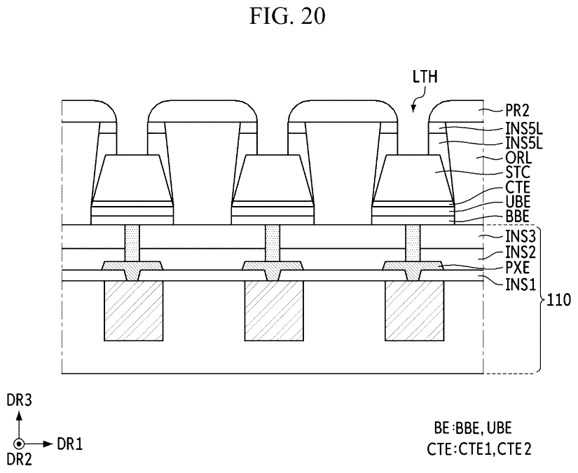

As shown in FIG. 20, the first element insulating layer INS4 and the second element insulating layer INS5 disposed on the top surface of the light emitting element LE of each of the light emitting areas not covered by the photoresist mask PR2 are removed. For example, the first element insulating layer INS4 and the second element insulating layer INS5 in the area overlapping the light emitting area are etched, thereby forming the through hole LTH.

As shown in FIG. 8, in case that the mask pattern HM used as a mask remains on the top surface of the light emitting element LE, the mask pattern HM may also be etched together in case that the through hole LTH is formed, thereby exposing the upper area of the light emitting element LE by the through hole LTH. The photoresist mask PR2 is removed. For example, the photoresist mask PR2 may be removed by an ashing process.

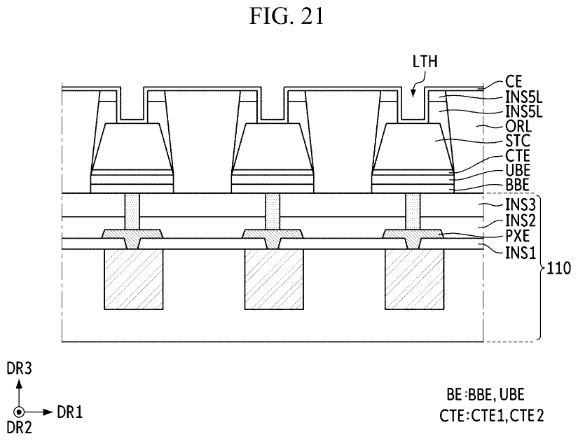

As shown in FIG. 21, a common electrode CE may be formed on the organic layer ORL and the light emitting element LE.

The common electrode CE may be in contact with the light emitting element LE exposed through the through hole LTH.

The common electrode CE may include a transparent conductive oxide (TCO) such as indium tin oxide (ITO) or indium zinc oxide (IZO).

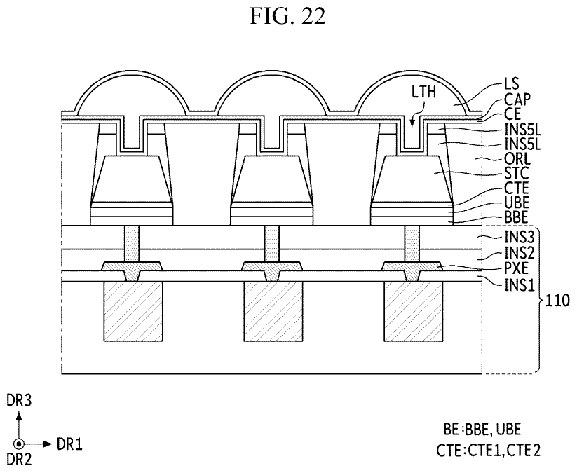

In an embodiment, in case that a display panel 100 including a light conversion layer and/or a color filter layer is to be manufactured as shown in FIG. 22, a process of forming a light conversion layer and/or a color filter layer on top of the light emitting element layer 120 or inside the light emitting element layer 120 may be additionally performed.

In an embodiment, in case that a display panel 100 including a lens-shaped optical structure LS as shown in FIG. 3 is to be manufactured, a process of attaching and/or forming a lens-shaped optical structure LS and a protective layer PSV or the like on the light emitting element layer 120 may be additionally performed.

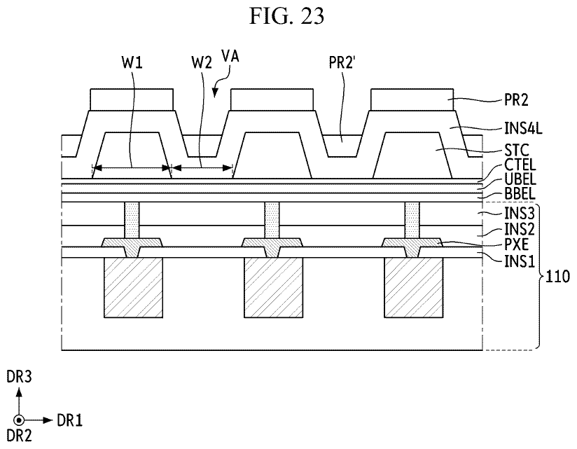

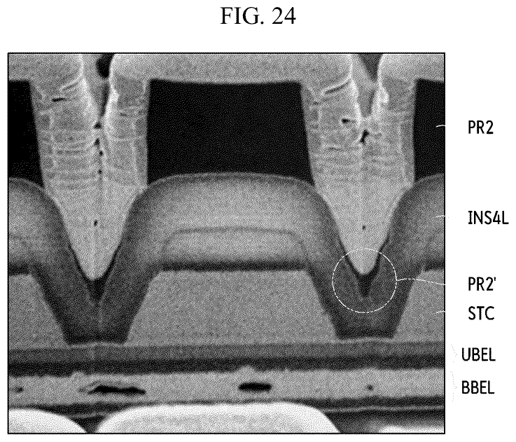

FIGS. 23 and 24 are drawings to illustrate an example in which a second element insulating layer is not formed in the flattening step of FIG. 9.

Referring to FIGS. 23 and 24, after forming a first element insulating layer INS4 on a semiconductor stack STC, a second element insulating layer INS5 may not be formed, and a photoresist mask PR2 for etching a connection electrode may be formed.

The photoresist mask PR2 may be disposed to overlap the light emitting area.

Since the area of the top surface of the semiconductor stack STC is narrow, it is difficult for the photoresist mask PR2 to precisely overlap the light emitting area. At this time, in case that the photoresist mask PR2 is formed narrowly and does not sufficiently overlap the semiconductor stack STC, the first element insulating layer INS4 may be etched on the side of the semiconductor stack STC and exposed on the side of the semiconductor stack STC.

The width W1 of the bottom surface of the semiconductor stack STC may be in a range of about 1.5 μm to about 2.5 μm, and the gap W2 between the semiconductor stacks STC may be about 0.5 μm.

On the other hand, in case that a sufficient margin is secured in the photoresist mask PR2, the photoresist mask PR2 is formed wider than one side or a side of the semiconductor stack STC. Therefore, an unwanted photoresist mask PR2′ may remain in the valley VA between the semiconductor stacks STC and the semiconductor stacks STC. If the photoresist mask PR2′ remains in the valley VA, the first element insulating layer INS4 is not etched between the semiconductor stacks STC and the semiconductor stacks STC. Therefore, a residual film of the first element insulating layer INS4 that is not etched between the semiconductor stacks STC and the semiconductor stacks STC, and since the residual film of the first element insulating layer INS4 interferes with the etching of the connection electrode layers UBEL and BBEL between the semiconductor stack STC and the semiconductor stack STC, a problem may occur in which the connection electrodes of the light emitting elements are not completely short-circuited in the future.

Therefore, the above problem may be solved by forming a second element insulating layer INS5 on the first element insulating layer INS4 and flattening the step formed by the semiconductor stack STC.

The display device according to one embodiment of the present disclosure can be applied to various electronic devices. The electronic device according to the one embodiment of the present disclosure includes the display device described above, and may further include modules or devices having additional functions in addition to the display device.

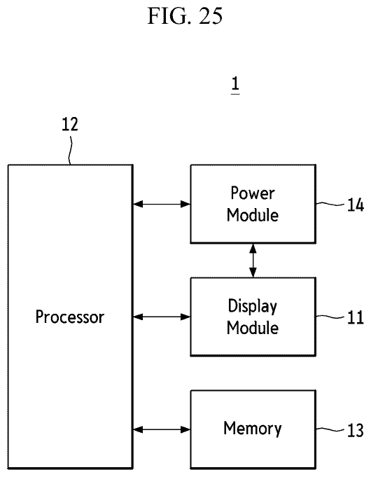

FIG. 25 is a block diagram of an electronic device according to one embodiment of the present disclosure.

Referring to FIG. 25, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

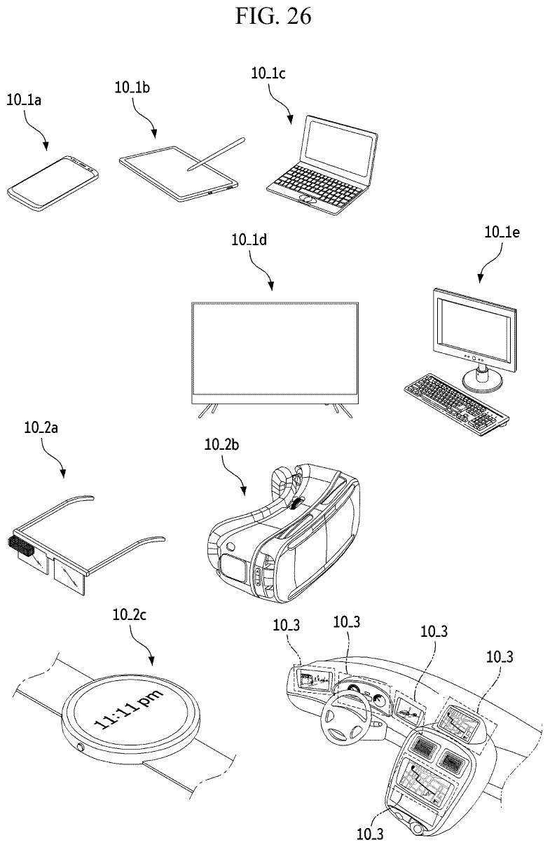

FIG. 26 is a schematic diagram of an electronic device according to various embodiments of the present disclosure.

Referring to FIG. 26, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a connection electrode disposed on a substrate;
light emitting elements disposed on the connection electrode and extending in a thickness direction of the substrate;
a first insulating layer surrounding a side surface and an upper surface of the light emitting elements;
a second insulating layer disposed on the first insulating layer disposed on the upper surface of the light emitting elements; and
a common electrode disposed on the upper surface of the light emitting elements,
wherein the common electrode is electrically connected to the light emitting elements through a through hole that penetrates the first insulating layer and the second insulating layer to expose the upper surface of the light emitting elements.

2. The display device of claim 1, wherein the side surface of the light emitting elements forms a first acute angle with a lower surface of the light emitting elements, and
an inclined surface of the first insulating layer forms a second acute angle with a surface extending from the lower surface of the light emitting elements, and the second acute angle is greater than the first acute angle.

3. The display device of claim 1, wherein a side surface of the connection electrode and a side surface of the first insulating layer are mutually aligned and disposed in a straight line.

4. The display device of claim 3, wherein the connection electrode includes a first connection electrode disposed at a lower surface of the connection electrode and a second connection electrode disposed on the first connection electrode, and
the first connection electrode and the second connection electrode have one or more layers.

5. The display device of claim 1, wherein a thickness of the second insulating layer on an upper portion of the light emitting elements is less than a thickness of the first insulating layer.

6. The display device of claim 1, wherein a slope of the first insulating layer becomes thicker as being closer from the connection electrode to the common electrode.

7. The display device of claim 1, further comprising a third insulating layer disposed between an upper portion of the light emitting elements and the first insulating layer.

8. The display device of claim 1, wherein the light emitting elements include a semiconductor stack and a contact electrode disposed at an end portion of the semiconductor stack, and
the semiconductor stack includes a first semiconductor layer, an active layer, and a second semiconductor layer that are sequentially stacked.

9. The display device of claim 8, wherein the semiconductor stack further includes a third semiconductor layer disposed on the second semiconductor layer.

10. The display device of claim 8, wherein the contact electrode includes a first contact electrode and a second contact electrode, and
the first contact electrode is disposed on a surface of the first semiconductor layer and the second contact electrode is disposed on an upper surface of the second semiconductor layer.

11. The display device of claim 1, further including a lens-shaped optical member on a light-emitting element layer including the light emitting elements and the common electrode.

12. A method of manufacturing a display device comprising:
bonding a backplane substrate including a first connection electrode layer and a base substrate having a second connection electrode layer and a semiconductor stack;
etching the semiconductor stack using a first mask;
forming a plurality of element insulating layers and planarizing steps formed by the semiconductor stack;
etching the first connection electrode layer and the second connection electrode layer using a second mask; and
forming a common electrode on the semiconductor stack.

13. The method of claim 12, wherein the planarizing of the steps formed by the semiconductor stack comprises:
forming a first element insulating layer to cover the semiconductor stack on the backplane substrate;
forming a second element insulating layer on the first element insulating layer; and
planarizing an upper surface of the second element insulating layer by a chemical mechanical polishing (CMP) process.

14. The method of claim 12, wherein the bonding of the base substrate comprises:
forming a first connection electrode layer on the backplane substrate;
forming a second connection electrode layer on the semiconductor stack of the base substrate;
arranging the first connection electrode layer and the second connection electrode layer to contact each other and the bonding the first connection electrode layer and the second connection electrode layer; and
removing the base substrate from the semiconductor stack.

15. The method of claim 12, wherein the first mask is an insulating hard mask.

16. The method of claim 12, wherein the second mask is a photoresist mask.

17. The method of claim 12, wherein the etching of the first connection electrode layer and the second connection electrode layer using the second mask comprises:
forming the second mask on a second insulating layer to overlap a light emitting area,
etching the first connection electrode layer and the second connection electrode layer using the second mask, and
removing the second mask by ashing.

18. The method of claim 12, wherein the forming of the common electrode on the semiconductor stack comprises:
filling an organic layer between light emitting elements including the semiconductor stack and the first and second connection electrode layers
forming a through hole penetrating a first element insulating layer and a second element insulating layer on an upper surface of the semiconductor stack to expose at least a portion of the upper surface of the semiconductor stack; and
forming the common electrode so that the common electrode electrically contacts the semiconductor stack through the through hole.

19. The method of claim 18, further comprising:
forming a lens-shaped optical member on a light emitting element layer including the light emitting elements and the common electrode.

20. An electronic device comprising:
a display panel including light emitting elements;
a connection electrode disposed on a substrate;
the light emitting elements disposed on the connection electrode and extending in a thickness direction of the substrate;
a first insulating layer surrounding a side surface and an upper surface of the light emitting elements;
a second insulating layer disposed on the first insulating layer disposed on the upper surface of the light emitting elements; and
a common electrode disposed on the upper surface of the light emitting elements,
wherein the common electrode is electrically connected to the light emitting elements through a through hole that penetrates the first insulating layer and the second insulating layer to expose the upper surface of the light emitting elements.
